(19) United States
(12) Patent Application Publication
(10) Pub. No.: US 2012/0270143 A1
(43) Pub. Date: Oct. 25, 2012

(54) RESIST UNDERLAYER COMPOSITION AND METHOD OF MANUFACTURING SEMICONDUCTOR INTEGRATED CIRCUIT DEVICES USING THE SAME

(76) Inventors: Hui-Chan YUN, Uiwang-si (KR); Sang-Kyun KIM, Uiwang-si (KR); Hyeon-Mo CHO, Uiwang-si (KR); Mi-Young KIM, Uiwang-si (KR); Sang-Ran KOH, Uiwang-si (KR); Yong-Jin CHUNG, Uiwang-si (KR); Jong-Seob KIM, Uiwang-si (KR)

(21) Appl. No.: 13/539,894

(22) Filed: Jul. 2, 2012

Related U.S. Application Data
(63) Continuation of application No. PCT/KR2010/008765, filed on Dec. 8, 2010.

(30) Foreign Application Priority Data
Dec. 30, 2009 (KR) 10-2009-0134325

(51) Int. Cl. C08L 83/04; G03F 7/20; B32B 3/30; C08K 5/3432

(52) U.S. Cl. 430/14; 524/588; 524/99; 430/313

(57) ABSTRACT

A resist underlayer composition, including a solvent, and an organosilane condensation polymerization product including about 10 to about 40 mol % of a structural unit represented by Chemical Formula 1:

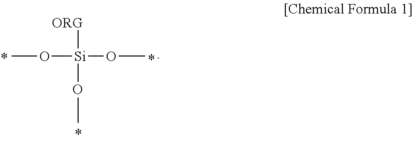

### CROSS-REFERENCE TO RELATED APPLICATIONS

This application is a continuation under 35 U.S.C. §120 of pending International Application No. PCT/KR2010/008765, filed on Dec. 8, 2010, and entitled “Resist Underlayer Composition and Method of Manufacturing Semiconductor Integrated Circuit Devices Using the Same,” the entire contents of which are hereby incorporated by reference.

This application claims priority under 35 U.S.C. §119 to Korean Patent Application No. 10-2009-0134325, filed on Dec. 30, 2009, in the Korean Intellectual Property Office, and entitled “Resist Underlayer Composition and Method of Manufacturing Semiconductor Integrated Circuit Devices Using the Same,” the entire contents of which are hereby incorporated by reference.

### BACKGROUND

Embodiments relate to a resist underlayer composition and a method of fabricating a semiconductor integrated circuit device using the same.

### SUMMARY

Embodiments are directed to a resist underlayer composition, including a solvent, and an organosilane condensation polymerization product including about 10 to about 40 mol % of a structural unit represented by Chemical Formula 1:

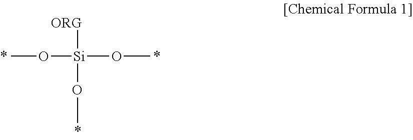

wherein, in Chemical Formula 1,

ORG may be selected from the group of:

a C6 to C30 functional group including a substituted or unsubstituted aromatic ring,

a C1 to C12 alkyl group,

and —Y—{Si(OR)₃}ₐ,

R may be a C1 to C6 alkyl group,

Y may be a linear or branched substituted or unsubstituted C1 to C20 alkylene group, or a C1 to C20 alkylene group including in a main chain a substituent selected from the group of an alkenylene group, an alkynylene group, an arylene group, a heterocyclic group, a urea group, an isocyanurate group, and a combination thereof, and

a may be 1 or 2.

The organosilane condensation polymerization product may further include a structural unit represented by Chemical Formulae 2 or 3:

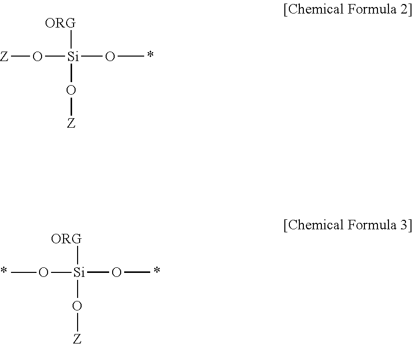

wherein, in Chemical Formulae 2 and 3,

ORG may be selected from the group of:

a C6 to C30 functional group including a substituted or unsubstituted aromatic ring,

a C1 to C12 alkyl group, and

—Y—{Si(OR)₃}ₐ,

R may be a C1 to C6 alkyl group,

Y may be a linear or branched substituted or unsubstituted C1 to C20 alkylene group, or a C1 to C20 alkylene group including in a main chain a substituent selected from the group of an alkenylene group, an alkynylene group, an arylene group, a heterocyclic group, a urea group, an isocyanurate group, and a combination thereof,

a may be 1 or 2, and

Z may be selected from the group of hydrogen and a C1 to C6 alkyl group.

The organosilane condensation polymerization product may be produced from a compound represented by Chemical Formula 4, a compound represented by Chemical Formula 5, and a compound represented by Chemical Formula 6 under acid or base catalysis:

[R¹O]₃Si—X [Chemical Formula 4]

[R²O]₃Si—R³ [Chemical Formula 5]

{[R⁴O]₃Si}ₙ—Y [Chemical Formula 6]

wherein, in Chemical Formulae 4 to 6,

R¹, R², and R⁴ each independently may be a C1 to C6 alkyl group,

R³ may be a C1 to C12 alkyl group,

X may be a C6 to C30 functional group including a substituted or unsubstituted aromatic ring,

Y may be a linear or branched substituted or unsubstituted C1 to C20 alkylene group, or a C1 to C20 alkylene group including in a main chain a substituent selected from the group of an alkenylene group, an alkynylene group, an arylene group, a heterocyclic group, a urea group, an isocyanurate group, and a combination thereof, and

n may be 2 or 3.

ORG may be the C6 to C30 functional group including a substituted or unsubstituted aromatic ring, and the C6 to C30 functional group including a substituted or unsubstituted aromatic ring may be represented by Chemical Formula 21:

*-(L)ₘ-X¹ [Chemical Formula 21]

wherein, in Chemical Formula 21,

L may be a linear or branched substituted or unsubstituted C1 to C20 alkylene group, wherein one or more carbons of the alkylene group are optionally substituted with a functional group selected from the group of an ether group (—O—), a carbonyl group (—CO—), an ester group (—COO—), an amine group (—NH—), and a combination thereof,

X¹ may be a substituted or unsubstituted C6 to C20 aryl group, a substituted or unsubstituted C7 to C20 arylcarbonyl group, or a substituted or unsubstituted C9 to C20 chromenone group, and

m may be 0 or 1.

The organosilane condensation polymerization product may be included in an amount of about 1 to about 50 wt % based on a total amount of the resist underlayer composition.

The resist underlayer composition may further include an additive selected from the group of a cross-linking agent, a radical stabilizer, a surfactant, and a combination thereof.

The resist underlayer composition may further include an additive selected from the group of pyridinium p-toluenesulfonate, amidosulfobetain-16, ammonium(−)-camphor-10-sulfonic acid ammonium salt, ammonium formate, alkyltriethylammonium formate, pyridinium formate, tetrabutyl ammonium acetate, tetrabutyl ammonium azide, tetrabutyl ammonium benzoate, tetrabutyl ammonium bisulfate, tetrabutyl ammonium bromide, tetrabutyl ammonium chloride, tetrabutyl ammonium cyanide, tetrabutyl ammonium fluoride, tetrabutyl ammonium iodide, tetrabutyl ammonium sulfate, tetrabutyl ammonium nitrate, tetrabutyl ammonium nitrite, tetrabutyl ammonium p-toluene sulfonate, tetrabutyl ammonium phosphate, and a combination thereof.

Embodiments are also directed to a method of manufacturing a semiconductor integrated circuit device, including:

providing a material layer on a substrate;

forming a first resist underlayer on the material layer;

coating the resist underlayer composition according to an embodiment on the first resist underlayer to form a second resist underlayer;

forming a radiation-sensitive imaging layer on the second resist underlayer;

patternwise exposing the radiation-sensitive imaging layer to radiation to form a pattern of radiation-exposed regions in the radiation-sensitive imaging layer;

selectively removing portions of the radiation-sensitive imaging layer and the second resist underlayer to expose portions of the first resist underlayer;

selectively removing portions of the patterned second resist underlayer and portions of the first resist underlayer to expose portions of the material layer; and

etching the exposed portions of the material layer to pattern the material layer.

The method may further include, between the processes of forming the second resist underlayer and forming a radiation-sensitive imaging layer, forming an anti-reflection coating.

Embodiments are also directed to a semiconductor integrated circuit device manufactured using the method of manufacturing a semiconductor integrated circuit device according to an embodiment.

Embodiments are also directed to a resist underlayer, including a resist underlayer polymer formed by cross-linking an organosilane condensation polymerization product including about 10 to about 40 mol % of a structural unit represented by Chemical Formula 1:

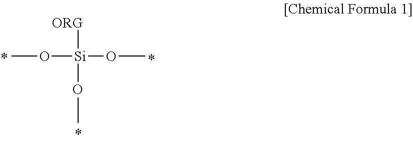

wherein, in Chemical Formula 1,

ORG may be selected from the group of:

a C6 to C30 functional group including a substituted or unsubstituted aromatic ring,

a C1 to C12 alkyl group,

and —Y—{Si(OR)₃}ₐ,

R may be a C1 to C6 alkyl group,

Y may be a linear or branched substituted or unsubstituted C1 to C20 alkylene group, or a C1 to C20 alkylene group including in a main chain a substituent selected from the group of an alkenylene group, an alkynylene group, an arylene group, a heterocyclic group, a urea group, an isocyanurate group, and a combination thereof, and

a may be 1 or 2.

### BRIEF DESCRIPTION OF THE DRAWING

Features will become apparent to those of ordinary skill in the art by describing in detail exemplary embodiments with reference to the attached drawing in which:

FIG. 1 illustrates a cross-sectional view of a multi-layer formed by sequentially stacking a first resist underlayer, a second resist underlayer, and a resist layer on a substrate.

### DETAILED DESCRIPTION

Example embodiments will now be described more fully hereinafter with reference to the accompanying drawing; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing FIGURE, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present.

As used herein, when a specific definition is not otherwise provided, the term “substituted” refers to one substituted with a C1 to C6 alkyl group or a C6 to C12 aryl group.

As used herein, when a specific definition is not otherwise provided, the term “alkyl” refers to a C1 to C6 alkyl; the term “alkylene” refers to C1 to C6 alkylene; the term “an aryl” refers to a C6 to C12 aryl; the term “arylene” refers to a C6 to C12 arylene; the term “alkenyl” refers to a C2 to C6 alkenyl; the term “alkenylene” refers to a C2 to C6 alkenylene; the term “alkynyl” refers to a C2 to C6 alkynyl; and the term “alkynylene” refers to a C2 to C6 alkynylene.

As used herein, when a specific definition is not otherwise provided, the term “heterocyclic group” refers to a C3 to C12 heteroarylene group, a C1 to C12 heterocycloalkylene group, a C2 to C12 heterocycloalkenylene group, a C2 to C12 heterocycloalkynylene group, or a fused ring thereof, and includes a heteroatom of N, O, S, or P in a ring. The heterocyclic group includes 1 to 5 heteroatoms.

According to an embodiment, a resist underlayer composition may include an organosilane condensation polymerization product including about 10 to about 40 mol % of the structural unit represented by the following Chemical Formula 1, and a solvent.

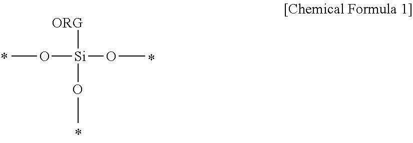

In Chemical Formula 1, ORG may be selected from the group of a C6 to C30 functional group including a substituted or unsubstituted aromatic ring, a C1 to C12 alkyl group, and —Y—{Si(OR)₃}ₐ. R may be a C1 to C6 alkyl group. Y may be a linear or branched substituted or unsubstituted C1 to C20 alkylene group, or a C1 to C20 alkylene group including in the main chain a substituent selected from the group of an alkenylene group, an alkynylene group, an arylene group, a heterocyclic group, a urea group, an isocyanurate group, and a combination thereof. a may be 1 or 2.

If the structural unit represented by Chemical Formula 1 is included within the above range, thin film coating performance, storage stability, and etching resistance may be improved. In particular, a resist underlayer composition according to an embodiment may have improved etching resistance against O₂ gas in a plasma state.

The organosilane condensation polymerization product may further include a structural unit represented by the following Chemical Formulae 2 or 3.

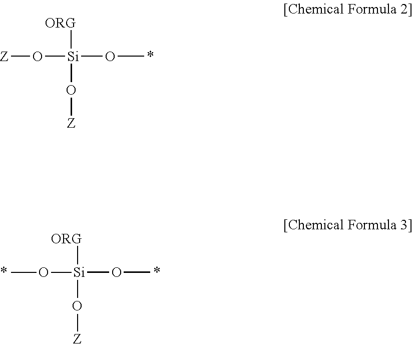

In Chemical Formulae 2 and 3, ORG may be selected from the group of a C6 to C30 functional group including a substituted or unsubstituted aromatic ring, a C1 to C12 alkyl group, and —Y—{Si(OR)₃}ₐ. R may be a C1 to C6 alkyl group. Y may be a linear or branched substituted or unsubstituted C1 to C20 alkylene group, or a C1 to C20 alkylene group including in the main chain a substituent selected from the group of an alkenylene group, an alkynylene group, an arylene group, a heterocyclic group, a urea group, an isocyanurate group, and a combination thereof. a may be 1 or 2. Z may be selected from the group of hydrogen and a C1 to C6 alkyl group.

The structural unit represented by the above Chemical Formula 2 may be included in a range of about 10 to about 40 mol %, and the structural unit represented by the above Chemical Formula 3 may be included in a range of about 20 to about 80 mol %.

The organosilane condensation polymerization product may be produced from the compounds represented by the following Chemical Formulae 4 to 6 under acid or a base catalysis.

[R¹O]₃Si—X [Chemical Formula 4]

[R²O]₃Si—R³ [Chemical Formula 5]

{[R⁴O]₃Si}ₙ—Y [Chemical Formula 6]

In Chemical Formulae 4 to 6, R¹, R² and R⁴ each independently may be a C1 to C6 alkyl group. R³ may be a C1 to C12 alkyl group. X may be a C6 to C30 functional group including a substituted or unsubstituted aromatic ring. Y may be a linear or branched substituted or unsubstituted C1 to C20 alkylene group, or a C1 to C20 alkylene group including in the main chain a substituent selected from the group of an alkenylene group, an alkynylene group, an arylene group, a heterocyclic group, a urea group, an isocyanurate group, and a combination thereof. n may be 2 or 3.

The compounds represented by the above Chemical Formulae 4 to 6 may be respectively included in amounts of about 5 to about 90 wt %, about 5 to about 90 wt %, and 0 to about 90 wt %, and thus absorbance, storage stability, and etching resistance of a resist underlayer composition may be improved. In particular, if a compound represented by the above Chemical Formula 4 is included in the above range, absorbance and etching resistance may be improved. If a compound represented by the above Chemical Formula 5 is included in the above range, absorbance and storage stability may be improved. In addition, if a compound represented by the above Chemical Formula 6 is included in the above range, etching resistance and storage stability may be improved. In addition, if a compound represented by the above Chemical Formula 6 is included in the above range, a hydrophilic effect may be applied to a thin film, which may improve interface affinity with an anti-reflection coating layer.

More specifically, the compound represented by the above Chemical Formula 6 may be the compounds represented by the following Chemical Formulae 7 to 20.

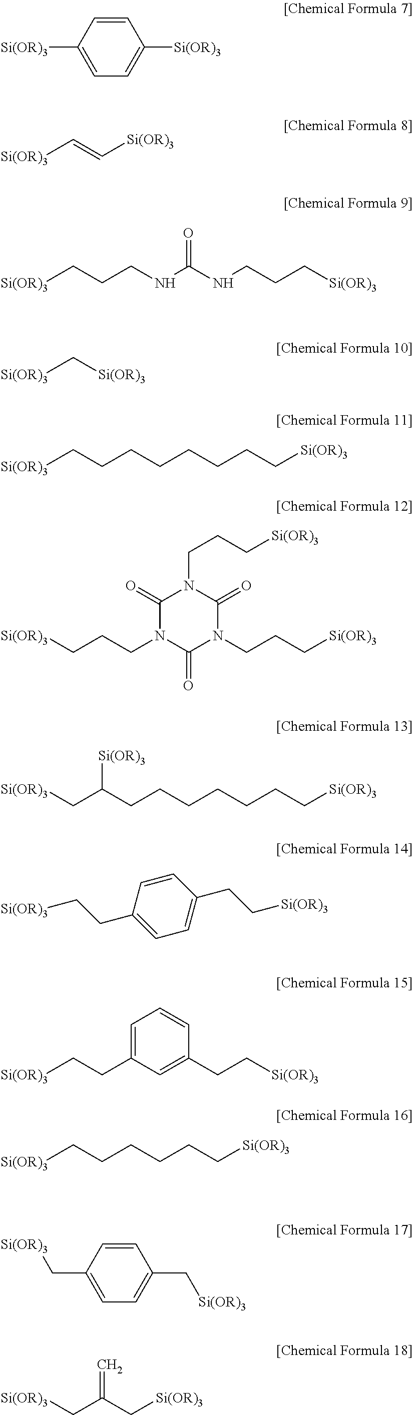

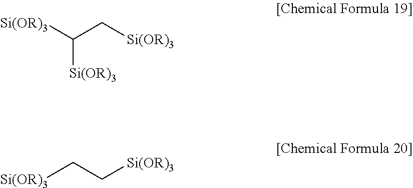

In the above Chemical Formulae, the “C6 to C30 functional group including a substituted or unsubstituted aromatic ring” may be represented by the following Chemical Formula 21.

*-(L)ₘ-X¹ [Chemical Formula 21]

In Chemical Formula 21, L may be a linear or branched substituted or unsubstituted C1 to C20 alkylene group, wherein one or two or more carbons of the alkylene group are optionally substituted with a functional group selected from the group of an ether group (—O—), a carbonyl group (—CO—), an ester group (—COO—), an amine group (—NH—), and a combination thereof. X¹ may be a substituted or unsubstituted C6 to C20 aryl group, a substituted or unsubstituted C7 to C20 arylcarbonyl group, or a substituted or unsubstituted C9 to C20 chromenone group. m may be 0 or 1.

Herein, in Chemical Formula 21, the term “substituted” refers to one substituted with a substituent selected from the group of a halogen, a hydroxy group, a nitro group, a C1 to C6 alkyl group, a C1 to C6 halogenated alkyl group, a C1 to C6 alkoxy group, a C2 to C6 alkenyl group, a C6 to C12 aryl group, and a C6 to C12 arylketone group.

For example, in the above Chemical Formulae, the “C6 to C30 functional group including a substituted or unsubstituted aromatic ring” may be represented by the following Chemical Formulae 22 to 42.

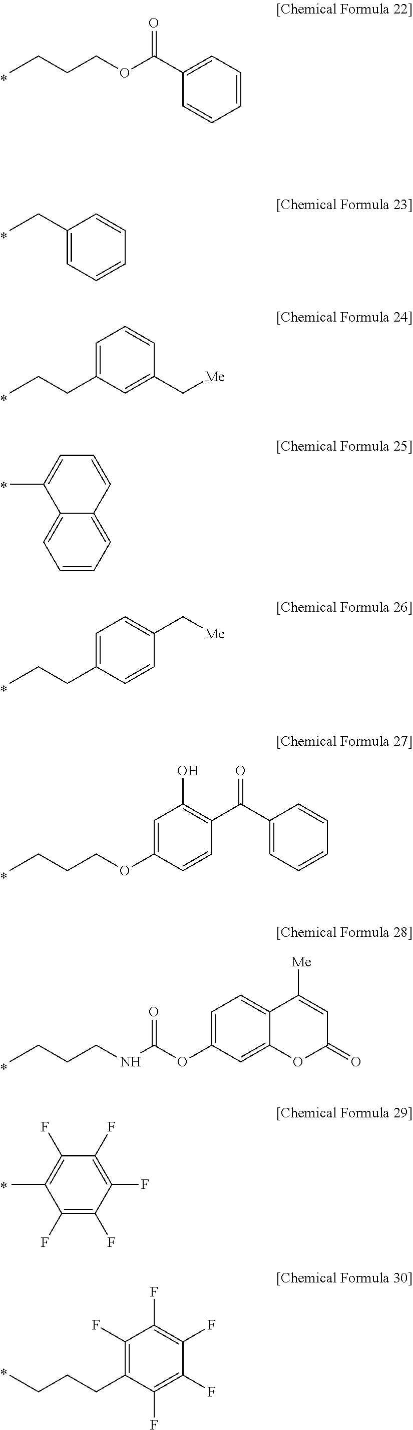

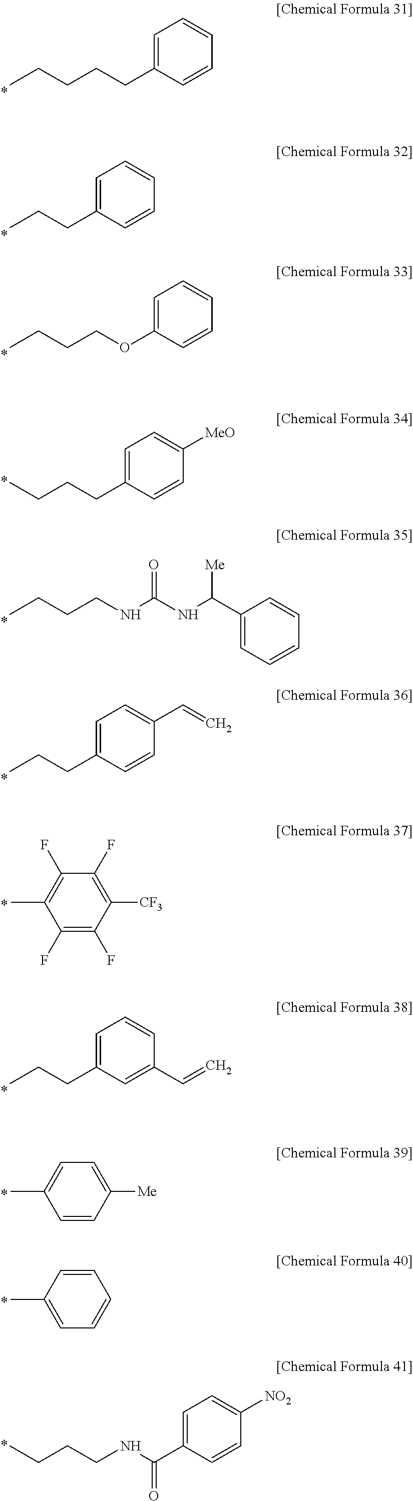

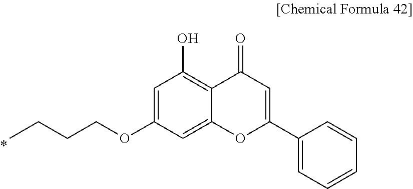

The organosilane condensation polymerization product may be produced through a hydrolysis and/or condensation polymerization reaction under acid or base catalysis.

The acid catalyst or base catalyst may control the speed of a hydrolysis reaction or a condensation polymerization reaction of the above Chemical Formulae, and thus may facilitate the acquisition of the organosilane condensation polymerization product having a desired molecular weight. The kinds of the acid and base catalysts may be a suitable kind of acid and base catalysts. For example, the acid catalyst may be selected from the group of hydrofluoric acid, hydrochloric acid, bromic acid, iodic acid, nitric acid, sulfuric acid, p-toluenesulfonic acid monohydrate, diethylsulfate, 2,4,4,6-tetrabromocyclohexadienone, benzoin tosylate, 2-nitrobenzyl tosylate, alkyl esters of organic sulfonic acids, and a combination thereof. The base catalyst may be selected from the group of an alkylamine (such as triethylamine and diethylamine), ammonia, sodium hydroxide, potassium hydroxide, pyridine, and a combination thereof. The acid catalyst or the base catalyst may be used in an amount of about 0.001 to about 5 parts by weight based on 100 parts by weight of the entire organosilane condensation polymerization product, and thus the reaction rate may be controlled and a condensation polymerization product of a desired molecular weight may be obtained.

The organosilane condensation polymerization product may be included in an amount of about 1 to about 50 wt % based on the total amount of the resist underlayer composition. If the organosilane condensation polymerization product is included within this range, coating capability of an underlayer composition may be improved.

The resist underlayer composition according to an embodiment includes the organosilane condensation polymerization product and a solvent. The solvent may prevent voids, and may dry the film slowly to thereby improve a planar property. The kind of the solvent may be a suitable kind of solvent. For example, the solvent may have a high boiling point such that the solvent volatilizes at a temperature slightly lower than a temperature at which the resist underlayer composition according to an embodiment is coated, dried, and solidified. Examples of the solvent include acetone, tetrahydrofuran, benzene, toluene, diethyl ether, chloroform, dichloromethane, ethyl acetate, propylene glycol methyl ether, propylene glycol ethyl ether, propylene glycol propyl ether, propylene glycol methyl ether acetate, propylene glycol ethyl ether acetate, propylene glycol propyl ether acetate, ethyl lactate, g-butyrolactone, methyl isobutyl ketone, or a combination thereof.

The resist underlayer composition according to an embodiment may further include an additive selected from the group of a cross-linking agent, a radical stabilizer, a surfactant, and a combination thereof.

The resist underlayer composition may include as an additive at least one from the group of pyridinium p-toluenesulfonate, amidosulfobetain-16, ammonium(−)-camphor-10-sulfonic acid ammonium salt, ammonium formate, alkyltriethylammonium formate, pyridinium formate, tetrabutyl ammonium acetate, tetrabutyl ammonium azide, tetrabutyl ammonium benzoate, tetrabutyl ammonium bisulfate, tetrabutyl ammonium bromide, tetrabutyl ammonium chloride, tetrabutyl ammonium cyanide, tetrabutyl ammonium fluoride, tetrabutyl ammonium iodide, tetrabutyl ammonium sulfate, tetrabutyl ammonium nitrate, tetrabutyl ammonium nitrite, tetrabutyl ammonium p-toluene sulfonate, tetrabutyl ammonium phosphate, and a combination thereof. These additives may be included in an amount of about 0.0001 to about 0.01 parts by weight based on 100 parts by weight of an organosilane condensation polymerization product, and thus etching resistance, solvent resistance, and storage stability of a resist underlayer composition may be improved.

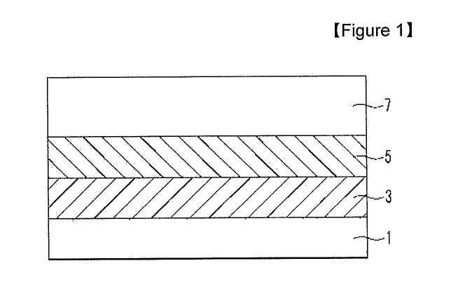

By way of example, a resist underlayer may be fabricated as shown in FIG. 1. More specifically, a first resist underlayer 3, which may be formed of an organic material, may be formed on a substrate 1, which may be formed of a silicon oxide layer, and a second resist underlayer 5 may be formed on the first resist underlayer 3. Also, a resist layer 7 may be formed on the second resist underlayer 5. The second resist underlayer 5 may have a higher etch selectivity with respect to the resist layer 7 than the substrate 1, and thus a pattern may be easily transferred even when a thin resist layer 7 is used. The first resist underlayer 3 may be etched and the pattern may be transferred by using the second resist underlayer 5 (having a pattern transferred thereto) as a mask, and then the pattern may be transferred to the substrate 1 by using the first resist underlayer 3 as a mask. Resultantly, a substrate may be etched to a desired depth by using a thinner resist layer 7.

According to an embodiment, a method of manufacturing a semiconductor integrated circuit device may include: (a) providing a material layer on a substrate; (b) forming a first resist underlayer on the material layer; (c) coating the resist underlayer composition on the first resist underlayer to form a second resist underlayer; (d) forming a radiation-sensitive imaging layer on the second resist underlayer; (e) patternwise exposing the radiation-sensitive imaging layer to radiation to form a pattern of radiation-exposed regions in the radiation-sensitive imaging layer; (f) selectively removing portions of the radiation-sensitive imaging layer and the second resist underlayer to expose portions of the first resist underlayer; (g) selectively removing portions of the patterned second resist underlayer and portions of the first resist underlayer to expose portions of the material layer; and (h) etching the exposed portions of the material layer to pattern the material layer.

The method may further include forming an anti-reflection coating between the processes of forming the second resist underlayer (c) and forming a radiation-sensitive imaging layer (d).

The second resist underlayer may include the structural unit represented by the above Chemical Formula 1 in an amount of about 10 to about 40 mol %.

By way of example, a method of forming a patterned material layer can be carried out in accordance with the following procedure.

First, a material (e.g., aluminum or silicon nitride (SiN)) to be patterned may be applied to a silicon substrate by a suitable technique. The material may be an electrically conductive, semi-conductive, magnetic or insulating material.

A first resist underlayer may include an organic material and may be provided on the patterned material. The first resist underlayer may include a suitable material (e.g., an organic material including carbon, hydrogen, oxygen, and the like) at a suitable thickness (e.g., about 200 Å to about 12000 Å).

Thereafter, the resist underlayer composition according to an embodiment may be spin-coated to a suitable thickness (e.g., about 500 Å to about 4000 Å) and baked at a suitable temperature (e.g., about 100° C. to about 300° C.) for a suitable time (e.g., about 10 seconds to about 10 minutes) to form a second resist underlayer.

A radiation-sensitive imaging layer may be formed on the second resist underlayer. Light exposure and development may be performed to form a pattern on the radiation-sensitive imaging layer. The patterned imaging layer (and an anti-reflective layer, if included) may be selectively removed to expose portions of the material layer, and dry etching may be performed using an etching gas. Examples of the etching gas include CHF₃, CF₄, CH₄, Cl₂, BCl₃, or a mixed gas. After forming a patterned material layer, a remaining material of the layers formed on the material layer may be removed using a suitable photoresist stripper.

According to an embodiment, a semiconductor integrated circuit device may be produced using the above method. Particularly, the method may be applied to the areas like a patterned material layer structure such as metal wiring lines, holes for contact or bias; an insulation section such as a multi-mask trench or a shallow trench insulation; and a trench for a capacitor structure such as in the designing of an integrated circuit device. In addition, the method may be applied to the formation of a patterned layer of oxide, nitride, polysilicon, and/or chromium.

The following Examples and Comparative Examples are provided in order to set forth particular details of one or more embodiments. However, it will be understood that the embodiments are not limited to the particular details described. Further, the Comparative Examples are set forth to highlight certain characteristics of certain embodiments, and are not to be construed as either limiting the scope of the invention as exemplified in the Examples or as necessarily being outside the scope of the invention in every respect.

### Comparative Example 1

189 g of phenyltrimethoxysilane, 520 g of methyltrimethoxysilane, and 1691 g of bis(trimethoxysilyl)methane were dissolved in 5600 g of propylene glycol monomethyl ether acetate (PGMEA) in a 10 l 4-necked flask including a mechanical agitator, a condenser, a dropping funnel, and a nitrogen gas injection tube, and 541 g of a 1000 ppm nitric acid aqueous solution was added thereto. Then, the solution mixture was hydrolyzed at 50° C. for one hour and then applied with a negative pressure to remove methanol produced therein. The resulting product was reacted at 50° C. for 7 days. After the reaction, an organosilane condensation polymerization product was produced.

The organosilane condensation polymerization product was condensed to have 20 wt % of a solid concentration by removing a solvent, thereby preparing a sample. 10.0 g of the sample was put in 90 g of PGMEA, thereby preparing a diluted solution. The diluted solution was mixed with 0.002 g of pyridinium p-toluenesulfonate, thereby preparing a resist underlayer composition.

The resist underlayer composition was spin-coated on a silicon wafer and baked at 240° C. for 1 minute to provide a 500 Å-thick resist underlayer.

### Comparative Example 2

490 g of phenyltrimethoxysilane, 287 g of methyltrimethoxysilane, and 1623 g of bis(trimethoxysilyl)methane were dissolved in 5600 g of PGMEA in a 10 l 4-necked flask including a mechanical agitator, a condenser, a dropping funnel, and a nitrogen gas injection tube, and 520 g of a 1000 ppm nitric acid aqueous solution was added to the solution. Then, the solution mixture was hydrolyzed at 50° C. for 1 hour and then applied with a negative pressure to remove methanol produced therein. The resulting product was reacted at 50° C. for 7 days. After the reaction, an organosilane condensation polymerization product was produced.

The organosilane condensation polymerization product was condensed to have 20 wt % of a solid concentration by removing a solvent, thereby preparing a sample. 10.0 g of the sample was mixed with 90 g of PGMEA, thereby preparing a diluted solution. The diluted solution was mixed with 0.002 g of pyridinium p-toluenesulfonate, thereby preparing a resist underlayer composition.

The resist underlayer composition was spin-coated on a silicon wafer and baked at 240° C. for 1 minute to provide a 500 Å-thick resist underlayer.

### Comparative Example 3

688 g of phenyltrimethoxysilane, 133 g of methyltrimethoxysilane, and 1578 g of bis(trimethoxysilyl)methane were dissolved in 5600 g of PGMEA in a 10 l 4-necked flask including a mechanical agitator, a condenser, a dropping funnel, and a nitrogen gas injection tube, and 505 g of a 1000 ppm nitric acid aqueous solution was added thereto. Then, the solution mixture was hydrolyzed at 50° C. for 1 hour and then applied with a negative pressure to remove methanol produced therein. The resulting product was reacted at 50° C. for 7 days. After the reaction, an organosilane condensation polymerization product was produced.

The organosilane condensation polymerization product was condensed to have 20 wt % of a solid concentration by removing a solvent, thereby preparing a sample. 10.0 g of the sample was mixed with 90 g of PGMEA, thereby preparing a diluted solution. The diluted solution was mixed with 0.002 g of pyridinium p-toluenesulfonate, thereby preparing a resist underlayer composition.

The resist underlayer composition was spin-coated on a silicon wafer and baked at 240° C. for 1 minute to provide a 500 Å-thick resist underlayer.

### Example 1

189 g of phenyltrimethoxysilane, 520 g of methyltrimethoxysilane, and 773.5 g of bis(trimethoxysilyl)methane were dissolved in 5600 g of PGMEA in a 10 l 4-necked flask including a mechanical agitator, a condenser, a dropping funnel, and a nitrogen gas injection tube, and 773.5 g of a 1000 ppm nitric acid aqueous solution was added thereto. Then, the solution mixture was hydrolyzed at 50° C. for 1 hour and then applied with a negative pressure to remove methanol produced therein. The resulting product was reacted at 50° C. for 7 days. After the reaction, an organosilane condensation polymerization product was produced.

The organosilane condensation polymerization product was condensed to have 20 wt % of a solid concentration by removing a solvent, thereby preparing a sample. 10.0 g of the sample was mixed with 90 g of PGMEA, thereby preparing a diluted solution. The diluted solution was mixed with 0.002 g of pyridinium p-toluenesulfonate, thereby preparing a resist underlayer composition.

The resist underlayer composition was spin-coated on a silicon wafer and baked at 240° C. for 1 minute to provide a 500 Å-thick resist underlayer.

### Example 2

189 g of phenyltrimethoxysilane, 520 g of methyltrimethoxysilane, and 773.5 g of bis(trimethoxysilyl)methane were dissolved in 5600 g of PGMEA in a 10 l 4-necked flask including a mechanical agitator, a condenser, a dropping funnel, and a nitrogen gas injection tube, and 1083 g of a 1000 ppm nitric acid aqueous solution was added thereto. Then, the solution mixture was hydrolyzed at 50° C. for 1 hour and then applied with a negative pressure to remove methanol produced therein. The resulting product was reacted at 50° C. for 7 days. After the reaction, an organosilane condensation polymerization product was produced.

The organosilane condensation polymerization product was condensed to have 20 wt % of a solid concentration to remove a solvent, thereby preparing a sample. 10.0 g of the sample was mixed with 90 g of PGMEA, thereby preparing a diluted solution. The diluted solution was mixed with 0.002 g of pyridinium p-toluenesulfonate, thereby preparing a resist underlayer composition.

The resist underlayer composition was spin-coated on a silicon wafer and baked at 240° C. for 1 minute to provide a 500 Å-thick resist underlayer.

### Example 3

189 g of phenyltrimethoxysilane, 520 g of methyltrimethoxysilane, and 1624 g of bis(trimethoxysilyl)methane were dissolved in 5600 g of PGMEA in a 10 l 4-necked flask including a mechanical agitator, a condenser, a dropping funnel, and a nitrogen gas injection tube, and then 773.5 g of a 1000 ppm nitric acid aqueous solution was added thereto. Then, the solution mixture was hydrolyzed at 50° C. for one hour and then applied with a negative pressure for 1 hour to remove methanol produced therein. The resulting product was reacted at 50° C. for 7 days. After the reaction, an organosilane condensation polymerization product was produced.

The organosilane condensation polymerization product was condensed to have 20 wt % of a solid concentration to remove a solvent, thereby preparing a sample. 10.0 g of the sample was mixed with 90 g of PGMEA, thereby preparing a diluted solution. The diluted solution was mixed with 0.002 g of pyridinium p-toluenesulfonate, thereby preparing a resist underlayer composition.

The resist underlayer composition was spin-coated on a silicon wafer and baked at 240° C. for 1 minute to provide a 500 Å-thick resist underlayer.

### Example 4

490 g of phenyltrimethoxysilane, 287 g of methyltrimethoxysilane, and 1623 g of bis(trimethoxysilyl)methane were dissolved in 5600 g of PGMEA in a 10 l 4-necked flask including a mechanical agitator, a condenser, a dropping funnel, and a nitrogen gas injection tube, and then 742 g of a 1000 ppm nitric acid an aqueous solution was added thereto. Then, the solution mixture was hydrolyzed at 50° C. for 1 hour and then applied with a negative pressure to remove methanol produced therein. The resulting product was reacted at 50° C. for 7 days. After the reaction, an organosilane condensation polymerization product was produced.

The organosilane condensation polymerization product was condensed to have 20 wt % of a solid concentration by removing a solvent, thereby preparing a sample. 10.0 g of the sample was mixed with 90 g of PGMEA, thereby preparing a diluted solution. The diluted solution was mixed with 0.002 g of pyridinium p-toluenesulfonate, thereby preparing a resist underlayer composition.

The resist underlayer composition was spin-coated on a silicon wafer and baked at 240° C. for 1 minute to provide a 500 Å-thick resist underlayer.

### Example 5

490 g of phenyltrimethoxysilane, 287 g of methyltrimethoxysilane, and 1623 g of bis(trimethoxysilyl)methane were dissolved in 5600 g of PGMEA in a 10 l 4-neck flask including a mechanical agitator, a condenser, a dropping funnel, and a nitrogen gas injection tube, and then 1039 g of a 1000 ppm nitric acid aqueous solution was added thereto. Then, the solution mixture was hydrolyzed at 50° C. for 1 hour and then applied with a negative pressure for one hour to remove methanol produced therein. The resulting product was reacted at 50° C. for 7 days. After the reaction, an organosilane condensation polymerization product was produced.

The organosilane condensation polymerization product was condensed to have 20 wt % of a solid concentration by removing a solvent, thereby preparing a sample. 10.0 g of the sample was mixed with 90 g of PGMEA, thereby preparing a diluted solution. The diluted solution was mixed with 0.002 g of pyridinium p-toluenesulfonate, thereby preparing a resist underlayer composition.

The resist underlayer composition was spin-coated on a silicon wafer and baked at 240° C. for 1 minute to provide a 500 Å-thick resist underlayer.

### Example 6

490 g of phenyltrimethoxysilane, 287 g of methyltrimethoxysilane, and 1623 g of bis(trimethoxysilyl)methane were dissolved in 5600 g of PGMEA in a 10 l 4-necked flask including a mechanical agitator, a condenser, a dropping funnel, and a nitrogen gas injection tube, and then 1559 g of a 1000 ppm nitric acid aqueous solution was added thereto. Then, the solution mixture was hydrolyzed at 50° C. for 1 hour and then applied with a negative pressure to remove methanol produced therein. The resulting product was reacted at 50° C. for 7 days. After the reaction, an organosilane condensation polymerization product was produced.

The organosilane condensation polymerization product was condensed to have 20 wt % of a solid concentration by removing a solvent, thereby preparing a sample. 10.0 g of the sample was mixed with 90 g of PGMEA, thereby preparing a diluted solution. The diluted solution was mixed with 0.002 g of pyridinium p-toluenesulfonate, thereby preparing a resist underlayer composition.

The resist underlayer composition was spin-coated on a silicon wafer and baked at 240° C. for 1 minute to provide a 500 Å-thick resist underlayer.

### Example 7

688 g of phenyltrimethoxysilane, 133 g of methyltrimethoxysilane, and 1578 g of bis(trimethoxysilyl)methane were dissolved in 5600 g of PGMEA in a 10 l 4-neck flask including a mechanical agitator, a condenser, a dropping funnel, and a nitrogen gas injection tube, and then 722 g of a 1000 ppm nitric acid aqueous solution was added thereto. Then, the solution mixture was hydrolyzed at 50° C. for 1 hour and then applied with a negative pressure to remove methanol produced therein. The resulting mixture was reacted at 50° C. for 7 days. After the reaction, an organosilane condensation polymerization product was produced.

The organosilane condensation polymerization product was condensed to have 20 wt % of a solid concentration by removing a solvent, thereby preparing a sample. 10.0 g of the sample was mixed with 90 g of PGMEA, thereby preparing a diluted solution. The diluted solution was mixed with 0.002 g of pyridinium p-toluenesulfonate to prepare a resist underlayer composition.

The resist underlayer composition was spin-coated on a silicon wafer and baked at 240° C. for 1 minute to provide a 500 Å-thick resist underlayer.

### Example 8

688 g of phenyltrimethoxysilane, 133 g of methyltrimethoxysilane, and 1578 g of bis(trimethoxysilyl)methane were dissolved in 5600 g of PGMEA in a 10 l 4-necked flask including a mechanical agitator, a condenser, a dropping funnel, and a nitrogen gas injection tube, and then 1010.5 g of a 1000 ppm nitric acid aqueous solution was added thereto. Then, the solution mixture was hydrolyzed at 50° C. for 1 hour and then applied with a negative pressure to remove methanol produced therein. The resulting product was reacted at 50° C. for 7 days. After the reaction, an organosilane condensation polymerization product was produced.

The organosilane condensation polymerization product was condensed to have 20 wt % of a solid concentration to remove a solvent, thereby preparing a sample. 10.0 g of the sample was mixed with 90 g of PGMEA, thereby preparing a diluted solution. The diluted solution was mixed with 0.002 g of pyridinium p-toluenesulfonate to prepare a resist underlayer composition.

The resist underlayer composition was spin-coated on a silicon wafer and baked at 240° C. for 1 minute to provide a 500 Å-thick resist underlayer.

### Example 9

688 g of phenyltrimethoxysilane, 133 g of methyltrimethoxysilane, and 1578 g of bis(trimethoxysilyl)methane were dissolved in 5600 g of PGMEA in a 10 l 4-necked flask including a mechanical agitator, a condenser, a dropping funnel, and a nitrogen gas injection tube, and 1516 g of a 1000 ppm nitric acid an aqueous solution was added thereto. Then, the solution mixture was hydrolyzed at 50° C. for 1 hour and then applied with a negative pressure to remove methanol produced therein. The resulting mixture was reacted at 50° C. for 7 days. After the reaction, an organosilane condensation polymerization product was produced.

The organosilane condensation polymerization product was condensed to have 20 wt % of a solid concentration by removing a solvent, thereby preparing a sample. 10.0 g of the sample was mixed with 90 g of PGMEA, thereby preparing a diluted solution. The diluted solution was mixed with 0.002 g of pyridinium p-toluenesulfonate, thereby preparing a resist underlayer composition.

The resist underlayer composition was spin-coated on a silicon wafer and baked at 240° C. for 1 minute to provide a 500 Å-thick resist underlayer.

### Experimental Example 1

The resist underlayer compositions according to Comparative Examples 1 to 3 and Examples 1 to 9 were tested regarding stability. The resist underlayer compositions were stored at 40° C. and sampled every seven day for 28 days to measure thickness (abbreviated as “T” in Table 1) and surface roughness (abbreviated as “SR” in Table 1) of a resist underlayer. Herein, the surface roughness was measured with scanning probe microscopy (SPM).

TABLE 1

| | 0 day | | 7^{th} day | | 14^{th} day | | 21^{st} day | | 28^{st} day | |
|---|---|---|---|---|---|---|---|---|---|---|
| | T | SR | T | SR | T | SR | T | SR | T | SR |
| | (Å) | (pm) | (Å) | (pm) | (Å) | (pm) | (Å) | (pm) | (Å) | (pm) |
| Comp. | 503 | 413 | 502 | 422 | 499 | 412 | 503 | 404 | 501 | 434 |
| Ex. 1 | | | | | | | | | | |
| Comp. | 500 | 425 | 511 | 418 | 503 | 411 | 502 | 422 | 503 | 411 |
| Ex. 2 | | | | | | | | | | |
| Comp. | 502 | 427 | 503 | 399 | 502 | 432 | 503 | 412 | 499 | 395 |
| Ex. 3 | | | | | | | | | | |
| Ex. 1 | 504 | 397 | 504 | 398 | 502 | 429 | 504 | 411 | 510 | 403 |
| Ex. 2 | 502 | 411 | 503 | 412 | 507 | 423 | 501 | 407 | 497 | 407 |
| Ex. 3 | 502 | 402 | 501 | 417 | 503 | 399 | 507 | 398 | 502 | 433 |
| Ex. 4 | 505 | 399 | 503 | 420 | 504 | 389 | 502 | 432 | 504 | 429 |
| Ex. 5 | 504 | 411 | 502 | 395 | 504 | 397 | 504 | 422 | 504 | 419 |
| Ex. 6 | 501 | 405 | 501 | 402 | 503 | 405 | 511 | 398 | 504 | 411 |
| Ex. 7 | 501 | 399 | 503 | 400 | 503 | 442 | 503 | 400 | 503 | 405 |
| Ex. 8 | 503 | 435 | 502 | 421 | 503 | 431 | 501 | 403 | 504 | 405 |
| Ex. 9 | 503 | 432 | 504 | 423 | 499 | 420 | 503 | 430 | 503 | 408 |

Referring to Table 1, the resist underlayer compositions according to Comparative Examples 1 to 3 and Examples 1 to 9 had very small thickness change (<10 Å) a predetermined time later, and thus showed excellent storage stability.

### Experimental Example 2

The resist underlayers according to Comparative Examples 1 to 3 and Examples 1 to 9 were measured regarding refractive index (n) and extinction coefficient (k) at 193 nm by using an ellipsometer (J. A. Woollam Co., Inc.).

TABLE 2

Optical property
at 193 nm

| | n | k |
|---|---|---|
| Comparative Example 1 | 1.69 | 0.14 |
| Comparative Example 2 | 1.78 | 0.36 |
| Comparative Example 3 | 1.80 | 0.48 |
| Example 1 | 1.69 | 0.14 |
| Example 2 | 1.69 | 0.14 |
| Example 3 | 1.69 | 0.14 |
| Example 4 | 1.78 | 0.36 |
| Example 5 | 1.78 | 0.36 |
| Example 6 | 1.78 | 0.36 |
| Example 7 | 1.80 | 0.48 |
| Example 8 | 1.80 | 0.48 |
| Example 9 | 1.80 | 0.48 |

Referring to Table 2, the resist underlayer composition according to an embodiment had an absorption spectrum in a DUV (deep UV), region and thus may be applied as a material with high anti-reflective properties.

### Experimental Example 3

The resist underlayers according to Comparative Examples 1 to 3 and Examples 1 to 9 were bulk dry-etched without a pattern under 90 mTorr of pressure, 400 W/250 W of RF power, 24 sccm of N₂, 12 sccm of O₂, and 500 sccm of Ar plasma condition for 15 seconds, and measured for thickness to calculate an etching rate per unit time. The results are provided in the following Table 3. Herein, N₂ and Ar are used as flowing gas, while O₂ is used as a main etching gas under the experiment conditions.

TABLE 3

Thin film characteristic

| | Etching resistance | Density |
|---|---|---|
| | (Å/sec) | (g/ml) |
| Comparative Example 1 | 7.04 | 1.24 |
| Comparative Example 2 | 7.43 | 1.25 |
| Comparative Example 3 | 7.62 | 1.25 |
| Example 1 | 5.01 | 1.39 |
| Example 2 | 4.44 | 1.44 |
| Example 3 | 4.32 | 1.44 |
| Example 4 | 5.39 | 1.37 |
| Example 5 | 4.76 | 1.39 |
| Example 6 | 4.55 | 1.40 |
| Example 7 | 5.46 | 1.38 |
| Example 8 | 4.75 | 1.41 |
| Example 9 | 4.52 | 1.41 |

Referring to Table 3, the resist underlayers according to Examples 1 to 9 had improved etching resistance against O₂ plasma compared with the resist underlayers according to Comparative Examples 1 to 3.

### Experimental Example 4

The resist underlayers according to Comparative Examples 1 to 3 and Examples 1 to 9 were examined regarding structure by using a ²⁹Si NMR spectrometer (Varian Unity 400). In the ²⁹Si NMR spectrum, a peak at about −65 ppm indicates a structure represented by the following Chemical Formula 1a, another peak at about −55 ppm indicates a structure represented by the following Chemical Formula 3a, and still another peak at about −45 ppm indicates a structure represented by the following Chemical Formula 2a. The peaks were calculated regarding area ratio (mol %) based on the spectrum. The results are provided in the following Table 4.

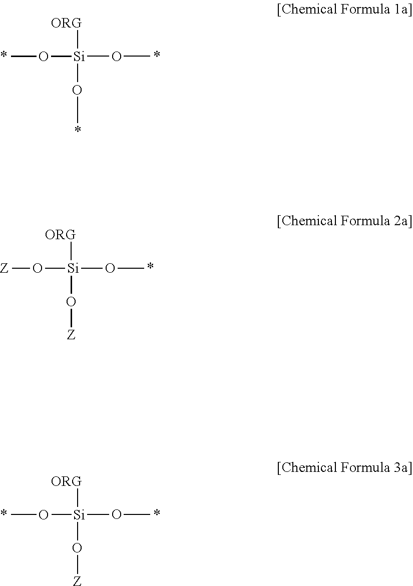

In Chemical Formulae 1a to 3a, ORG is selected from the group of a methyl group, a phenyl group, and a trimethoxysilylmethyl group, and Z is a methyl group.

TABLE 4

| | Structure | Structure | Structure |
|---|---|---|---|
| | Represented | Represented | Represented |
| | By Chemical | By Chemical | By Chemical |
| | Formula 1a | Formula 2a | Formula 3a |
| Comp. Example 1 | 8.9 | 31.6 | 59.5 |
| Comp. Example 2 | 9.0 | 31.7 | 59.3 |
| Comp. Example 3 | 8.6 | 31.6 | 59.8 |
| Example 1 | 21.1 | 26.3 | 52.6 |
| Example 2 | 22.5 | 27.5 | 50.0 |
| Example 3 | 24.5 | 28.3 | 47.2 |
| Example 4 | 21.2 | 26.5 | 52.3 |
| Example 5 | 22.5 | 27.6 | 49.9 |
| Example 6 | 23.9 | 28.1 | 48.0 |
| Example 7 | 21.3 | 26.7 | 52.0 |
| Example 8 | 22.8 | 27.1 | 50.1 |
| Example 9 | 23.6 | 27.5 | 48.9 |

Referring to Table 4, the resist underlayer compositions according to Examples 1-9 include an organosilane condensation polymerization product including a structural unit represented by Chemical Formula 1a in an amount of 10 to 40 mol %, and thus include more silicon, thereby providing a resist underlayer with excellent storage stability and layer characteristic without using a silane compound. In particular, the resist underlayer compositions according to Examples 1-9 had excellent etching resistance against gas plasma, thereby allowing an desired pattern to be effectively transmitted.

By way of summary and review, in lithography processes, it may be desirable to minimize reflection between a resist layer and a substrate in order to increase a resolution. For this reason, an anti-reflective coating (ARC) material may be used between the resist layer and the substrate to improve the resolution. However, the anti-reflective coating material may be similar to a resist material in terms of basic composition, and thus the anti-reflective coating material may have a poor etching selectivity for a resist layer with an image imprinted therein. Therefore, an additional lithography process in the subsequent etching process may be required.

In addition, a resist material may not have sufficient resistance against the subsequent etching process. When a resist layer is thin, when a substrate to be etched is thick, when an etch depth is required to be deep, or when a particular etchant is required for a particular substrate, a resist underlayer may be used. The resist underlayer may include two layers having an excellent etching selectivity. However, it may be difficult to achieve a resist underlayer with excellent etching resistance.

Also, a resist underlayer may be prepared in a chemical vapor deposition (CVD) method during mass production of a semiconductor device. However, when a resist underlayer is deposited in the CVD method, particles may be generated inside the resist underlayer and may be difficult to detect. In addition, if the resist underlayer has a pattern with a narrower line, even a small amount of particles therein may have a poor effect on electric characteristics of a final device. Thus, the CVD method may result in a longer process and expensive equipment.

Furthermore, when a resist underlayer composition is used to form a second resist underlayer and includes an organosilane condensation polymerization product, a silanol group with high reactivity may remain, and thus storage stability may be deteriorated. In particular, when the resist underlayer composition is stored for a long time, the silanol group may have a condensation reaction, and thus the molecular weight of the organosilane condensation polymerization product may increase. When the organosilane condensation polymerization product increases a molecular weight, the resist underlayer composition may become gel.

Thus, it would be beneficial for a resist underlayer composition to be available for spin-on-coating, to be able to easily control particles, to be able to be used in a fast process and at a low cost, to be able to have improved storage stability, and to have improved etching resistance so as to improve pattern transfer characteristics.

The resist underlayer composition according to an embodiment may include more silicon without using a silane compound, and thus may provide a resist underlayer with excellent storage stability and layer characteristic (e.g., easily control particles). In particular, the resist underlayer composition may have excellent etching resistance against gas plasma, and thus may effectively transmit a desired pattern. Also, the resist underlayer composition may allow easily control of a hydrophilic or hydrophobic surface. The resist underlayer composition also may be capable of being coated using a spin-on-coating method (e.g., to allow fast processing and low cost).

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A resist underlayer composition, comprising:
a solvent; and
an organosilane condensation polymerization product including about 10 to about 40 mol % of a structural unit represented by Chemical Formula 1: 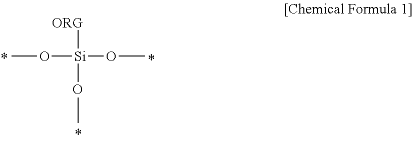
wherein, in Chemical Formula 1,
ORG is selected from the group of:
a C6 to C30 functional group including a substituted or unsubstituted aromatic ring,
a C1 to C12 alkyl group,
and —Y—{Si(OR)₃}ₐ,
R is a C1 to C6 alkyl group,
Y is a linear or branched substituted or unsubstituted C1 to C20 alkylene group, or a C1 to C20 alkylene group including in a main chain a substituent selected from the group of an alkenylene group, an alkynylene group, an arylene group, a heterocyclic group, a urea group, an isocyanurate group, and a combination thereof, and
a is 1 or 2.

2. The resist underlayer composition as claimed in claim 1, wherein the organosilane condensation polymerization product further includes a structural unit represented by Chemical Formulae 2 or 3: 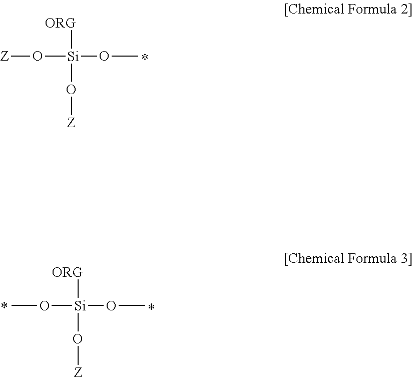
wherein, in Chemical Formulae 2 and 3,
ORG is selected from the group of:
a C6 to C30 functional group including a substituted or unsubstituted aromatic ring,
a C1 to C12 alkyl group, and
—Y—{Si(OR)₃}ₐ,
R is a C1 to C6 alkyl group,
Y is a linear or branched substituted or unsubstituted C1 to C20 alkylene group, or a C1 to C20 alkylene group including in a main chain a substituent selected from the group of an alkenylene group, an alkynylene group, an arylene group, a heterocyclic group, a urea group, an isocyanurate group, and a combination thereof,
a is 1 or 2, and
Z is selected from the group of hydrogen and a C1 to C6 alkyl group.

3. The resist underlayer composition as claimed in claim 1, wherein the organosilane condensation polymerization product is produced from a compound represented by Chemical Formula 4, a compound represented by Chemical Formula 5, and a compound represented by Chemical Formula 6 under acid or base catalysis:
[R¹O]₃Si—X [Chemical Formula 4]
[R²O]₃Si—R³ [Chemical Formula 5]
{[R⁴O]₃Si}ₙ—Y [Chemical Formula 6]
wherein, in Chemical Formulae 4 to 6,
R¹, R², and R⁴ are each independently a C1 to C6 alkyl group,
R³ is a C1 to C12 alkyl group,
X is a C6 to C30 functional group including a substituted or unsubstituted aromatic ring,
Y is a linear or branched substituted or unsubstituted C1 to C20 alkylene group, or a C1 to C20 alkylene group including in a main chain a substituent selected from the group of an alkenylene group, an alkynylene group, an arylene group, a heterocyclic group, a urea group, an isocyanurate group, and a combination thereof, and
n is 2 or 3.

4. The resist underlayer composition as claimed in claim 1, wherein:
ORG is the C6 to C30 functional group including a substituted or unsubstituted aromatic ring, and
the C6 to C30 functional group including a substituted or unsubstituted aromatic ring is represented by Chemical Formula 21:
*-(L)ₘ-X¹ [Chemical Formula 21]
wherein, in Chemical Formula 21,
L is a linear or branched substituted or unsubstituted C1 to C20 alkylene group, wherein one or more carbons of the alkylene group are optionally substituted with a functional group selected from the group of an ether group (—O—), a carbonyl group (—CO—), an ester group (—COO—), an amine group (—NH—), and a combination thereof,
X¹ is a substituted or unsubstituted C6 to C20 aryl group, a substituted or unsubstituted C7 to C20 arylcarbonyl group, or a substituted or unsubstituted C9 to C20 chromenone group, and
m is 0 or 1.

5. The resist underlayer composition as claimed in claim 1, wherein the organosilane condensation polymerization product is included in an amount of about 1 to about 50 wt % based on a total amount of the resist underlayer composition.

6. The resist underlayer composition as claimed in claim 1, wherein the resist underlayer composition further comprises an additive selected from the group of a cross-linking agent, a radical stabilizer, a surfactant, and a combination thereof.

7. The resist underlayer composition as claimed in claim 1, wherein the resist underlayer composition further comprises an additive selected from the group of pyridinium p-toluenesulfonate, amidosulfobetain-16, ammonium(−)-camphor-10-sulfonic acid ammonium salt, ammonium formate, alkyltriethylammonium formate, pyridinium formate, tetrabutyl ammonium acetate, tetrabutyl ammonium azide, tetrabutyl ammonium benzoate, tetrabutyl ammonium bisulfate, tetrabutyl ammonium bromide, tetrabutyl ammonium chloride, tetrabutyl ammonium cyanide, tetrabutyl ammonium fluoride, tetrabutyl ammonium iodide, tetrabutyl ammonium sulfate, tetrabutyl ammonium nitrate, tetrabutyl ammonium nitrite, tetrabutyl ammonium p-toluene sulfonate, tetrabutyl ammonium phosphate, and a combination thereof.

8. A method of manufacturing a semiconductor integrated circuit device, comprising:
providing a material layer on a substrate;
forming a first resist underlayer on the material layer;
coating the resist underlayer composition according to claim 1 on the first resist underlayer to form a second resist underlayer;
forming a radiation-sensitive imaging layer on the second resist underlayer;
patternwise exposing the radiation-sensitive imaging layer to radiation to form a pattern of radiation-exposed regions in the radiation-sensitive imaging layer;
selectively removing portions of the radiation-sensitive imaging layer and the second resist underlayer to expose portions of the first resist underlayer;
selectively removing portions of the patterned second resist underlayer and portions of the first resist underlayer to expose portions of the material layer; and
etching the exposed portions of the material layer to pattern the material layer.

9. The method as claimed in claim 8, further comprising, between the processes of forming the second resist underlayer and forming a radiation-sensitive imaging layer, forming an anti-reflection coating.

10. A semiconductor integrated circuit device manufactured using the method of manufacturing a semiconductor integrated circuit device as claimed in claim 8.

11. A resist underlayer, comprising:
a resist underlayer polymer formed by cross-linking an organosilane condensation polymerization product including about 10 to about 40 mol % of a structural unit represented by Chemical Formula 1: 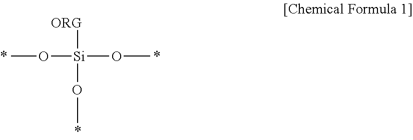
wherein, in Chemical Formula 1,
ORG is selected from the group of:
a C6 to C30 functional group including a substituted or unsubstituted aromatic ring,
a C1 to C12 alkyl group,
and —Y—{Si(OR)₃}ₐ,
R is a C1 to C6 alkyl group,
Y is a linear or branched substituted or unsubstituted C1 to C20 alkylene group, or a C1 to C20 alkylene group including in a main chain a substituent selected from the group of an alkenylene group, an alkynylene group, an arylene group, a heterocyclic group, a urea group, an isocyanurate group, and a combination thereof, and
a is 1 or 2.
